(19) United States
(12) Patent Application Publication
(10) Pub. No.: US 2010/0187445 A1
(43) Pub. Date: Jul. 29, 2010

(54) ION BOMBARDMENT METHOD FOR REDUCING THE POROSITY OF METAL DEPOSITS

(75) Inventor: Denis Busardo, Gonneville-sur-Mer (FR)

Correspondence Address: HAMRE, SCHUMANN, MUELLER & LARSON, P.C., P.O. BOX 2902, MINNEAPOLIS, MN, 55402-0902, US

(73) Assignee: QUERTECH INGENIERIE, Caen (FR)

(21) Appl. No.: 12/677,548

(22) PCT Filed: Sep. 11, 2008
(86) PCT No.: PCT/FR08/51623

§ 371 Date: Mar. 11, 2010

(30) Foreign Application Priority Data
Sep. 11, 2007 (FR) 0706341

(51) Int. Cl. H01J 37/317; H01J 37/02

(52) U.S. Cl. 250/492.3

(57) ABSTRACT

The invention relates to a method for treating a metal deposit to reduce or eliminate the porosity thereof by bombarding the same with an ion source. The source is, for example, an electron cyclotron resonance (RCE) source. The metal can be gold. The ion bombardment has the effect of sealing the porosity of the metal deposit according to the type, energy, amount and angle of incidence of the ions.

The invention relates to an ion bombardment method for reducing and even eliminating the porosity of metal deposits.

The invention is intended in particular to reduce and even eliminate the porosity of gold deposits, but cannot be limited to deposits of this metal. The method according to the invention is also capable of improving the properties of deposits of other metals, for example, silver, nickel, platinum, zinc, tin or alloys.

### BACKGROUND OF THE INVENTION

The invention is applicable in particular in the field of connectors, in which it is sought to increase the lifetime of connectors by limiting and even eliminating the risks of corrosion. This corrosion is generally due to the porosity of the gold layers, which can allow corrosive agents present in the air to pass and which are capable of attacking substrates, in particular copper, nickel or zinc.

Gold is a metal known for its qualities of inoxidability and its insensitivity to corrosive agents such as, for example, sulfuric acid. Aqua regia is among the rare mixtures enabling gold to be attacked. Gold is a good electrical conductor. It s conductivity is practically as good as that of copper.

Owing to its qualities, the connector industry commonly uses gold as anticorrosive coating in order to protect the connectors while maintaining their capacity to allow the current to pass.

Certain connectors are produced from flat copper, zinc or nickel strips pre-coated with a gold deposit of around 0.8 μm.

In the field of connectors, the deposition of gold is usually performed electrolytically.

The gold deposit is thus in the form of a laminar structure through which pores pass through in places, which have the effect of limiting and even destroying its anticorrosive properties. The formation of these pores is inherent to the electrolytic gold deposition process. These pores have a tendency to form more easily when the thickness of the gold is low.

Currently, the gold deposits are around 0.8 μm and have a porosity resulting in pores of which the diameters may reach 1 μm.

The connectors operate in air generally containing a small amount of SO₂, NO₂ and Cl₂. The porosity of the gold deposits is capable of allowing these corrosive agents to pass, resulting in the formation of corrosive products consisting of nitride, sulfate and copper, nickel or zinc chloride on the surface of the connectors. The appearance of these corrosive products can cause a malfunction of the connector.

For economic reasons, the connector industry seeks to reduce the thickness of the deposits. A change in the gold thickness from 0.8 μm to 0.2 μm would divide the cost of the deposit by four. This objective encounters technical constraints: it has generally been observed that a decrease in the thickness of the deposit leads to greater porosity, which in turn reduces the lifetime of the connector.

The connector industry is currently seeking a solution enabling the thickness of gold deposits to be reduced while reducing or even eliminating the permeability thereof to corrosive agents.

The invention is intended to overcome the limits, disadvantages and technical problems mentioned above.

### SUMMARY OF THE INVENTION

The invention thus proposes a method for ion treatment of the porosity of a porous metal deposit deposited on a substrate including a step in which the surface of said metal deposit is subjected to an ion beam (F).

It is thus possible to reduce and even eliminate the porosity of metal deposits, in particular gold, with which, for example, copper, nickel or zinc strips used in connectors are coated.

Owing to the method of this invention, the treatment of the porosity of metal deposits, in particular gold, enables the initial electrical, thermal and mechanical properties to be preserved.

Owing to the method of this invention, the treatment of metal deposits, in particular gold, enables the initial color to be preserved.

Owing to the method of this invention, the treatment of metal deposits, in particular gold, does not require long treatment times.

Owing to the method of this invention, the treatment of metal deposits, in particular gold, is inexpensive and enables it to be used in an industrial context, as the cost thereof is not prohibitive with respect to the costs of other methods.

According to an embodiment, the ion beam is emitted by a cyclotron resonance source (ECR).

According to an embodiment, the angle of incidence (α) of the ion beam is between a minimum angle of incidence (αₘ) and substantially 80°, in which the angle of incidence (α) of the beam is measured with respect to the normal to the surface of the porous metal deposit to be treated and in which the minimum angle of incidence (αₘ) is determined according to the radius (R) of the pores and the thickness (e) of the metal deposit to be treated according to the formula:

αₘ=arc tg(R/e)

The choice of the angle of incidence from the range mentioned enables the conditions of rearrangement of the material of the porous metal deposit to be optimized, and the experiments conducted by the inventors have shown that, owing to this choice, it is possible to fill the metal deposit porosity, in particular gold deposits obtained electrolytically.

According to another embodiment, the angle of incidence (α) of the ion beam is substantially coincident with the normal to the surface of the metal deposit to be treated.

Under these conditions, it is noted that the rearrangement of the material of the porous metal deposit is less effective than under the conditions above. This reduced efficacy may be compensated by a rearrangement of the surface of the substrate. Indeed, when the angle of incidence of the beam is substantially coincident with the normal to the surface of the metal deposit, the inventors were able to observe that the ions of the beam could be propagated through the porosities of the deposit and reach the substrate. This effect is very significant when the pores have a substantially cylindrical shape and lead to the surface of the metal deposit and to the surface of the substrate. The ions interacting with the substrate are then capable of enabling ion implantations in the substrate, enabling the hardness and/or corrosion resistance properties to be improved.

According to an embodiment, the beam is oriented in two opposite directions with respect to the normal to the surface of the porous metal deposit to be treated, in the same plane substantially perpendicular to said surface.

The inventors were able to observe that, under these conditions, the efficacy of the treatment of porosities was significantly improved with respect to the use of a beam oriented in a single directions.

According to another embodiment, the beam is oriented with respect to the surface of the porous metal deposit according to a plurality of angles of incidence and/or a plurality of planes substantially perpendicular to the surface of the metal deposit to be treated.

The inventors were also able to observe that this embodiment enables the efficacy of the treatment to be very significantly improved.

According to an embodiment, combining the two embodiments mentioned above, the beam is oriented successively according to the same angle of incidence α, and according to four directions which are deduced by a 90° rotation with respect to the axis perpendicular to the surface, namely with respect to the normal to the surface of the metal deposit to be treated.

According to different embodiments which can be combined:
the total dose of ions implanted is calculated so as to enable, at least once, the movement of each metal atom in the implantation depth;
the ion beam is formed by ionized atoms in which the atoms are chosen from the list consisting of helium (He), nitrogen (N), neon (Ne), argon (Ar), krypton (Kr) and xenon (Xe);
the ion beam extraction voltage is greater than or equal to 10 kV;
the porous metal deposit is an electrolytic deposit;
the porous metal deposit is a gold deposit.

It is noted that, to limit the volume and the complexity of the equipment used, it may be desirable to limit the extraction voltage of the ion beam to a maximum of 300 kV.

Without wanting to be bound by any scientific theory, the following mechanism can be proposed in order to take into account the advantageous effects of the method according to the invention: when an accelerated ion enters a material, it transfers, by atomic collision, some of its energy to the atoms located in its path. These atoms in turn cause collisions which ensure, in the form of a cascade, ballistic mixing of the material.

The heavier the incident ion is, the more effective this ballistic mixing is. This ballistic mixing is assessed by the number of collisions per unit of the course that an incident ion can cause in a given material.

For example, for a helium ion implanted with an energy of 70 keV in gold, this number is estimated at 0.015 atoms/Angstrom. As its course is 4000 Angstom in gold, the helium ion jostles 60 atoms over its passage. A nitrogen ion implanted with an energy of 70 keV in gold jostles 0.35 atoms/Angstrom over a course of 1800 Angstrom, i.e. 630 atoms. It is noted that, for the same energy, the efficacy of a nitrogen ion is 10 times greater than that of helium, but over only half the course.

According to this example, and based on these numbers, it is estimated that a dose of 10¹⁶ helium ions/cm² is enough to jostle each gold atom located in an implantation thickness of 4000 Angstrom four times. For the same does of nitrogen ions, each atom located in a thickness of 2000 Angstrom is jostled forty times. In both cases, these doses are sufficient to enable the implantation layer to be totally mixed and the pores present in the gold deposit to be partially or totally filled. These doses do not modify the composition of the gold deposit insofar as they represent only around 1 percent of the gold atoms.

As an example, it is noted that the porosity of the gold deposits obtained electrolytically involves a distribution of pores of which the diameter may vary from 0 to 1 μm through a thickness of around 0.8 μm. It is sought to reduce these thicknesses to 0.2 μm.

According to an embodiment, the method of the invention proposes treating the gold deposit with an ion dose that enables the implantation thickness to be mixed at least once. The ions have an energy that must enable them to partially or totally pass through the deposit. The higher the implantation depth, and therefore the energy of the ions is, the more effective the treatment is.

The inventors have also observed that it may be advantageous to reduce the gold thickness so as to enable nitrogen ions to treat not only the deposit by ballistic mixing but also the substrate. Indeed, the nitrogen ions implanted in the substrate can, by their action, delay corrosion. As an example, it is possible to treat with nitrogen ions of 70 keV. Ballistic mixing would then seal the gold deposit of 0.1 μm and an anticorrosive barrier of 0.1 μm in the substrate.

According to an embodiment, the method of the invention proposes treating the metal deposit, in particular gold, with four doses, at the same angle of incidence and successively in four directions, which are deduced by a 90° rotation with respect to the axis perpendicular to the surface. Each dose preferably enables the atoms contained in the thickness of the deposit to be mixed at least one time. The minimum angle of incidence of the beam can be determined so that its tangent is equal to the ratio of the radius of the pores to the thickness of the gold deposit. For example, if the radius is 0.5 μM and the thickness of the deposit is 0.5 μm, the beam has an angle of incident of at least 45°. An increase in the efficacy of the ballistic mixing is thus observed.

According to different embodiments of the method of the invention, the implantation strategy can be as follows:
For high angles of incidence, in other words, substantially shear with respect to the surface, it is noted that it is preferable to use light ions such as helium, which has the advantage of more deeply penetrating the apparent thickness of the deposit and limiting the risks of spraying. It is advantageous to make sure that the dose of helium ions does not exceed several percent in order to limit the modification of the composition of the gold deposit from an electrical, mechanical or aesthetic perspective.
For lower angles of incidence, it may be preferable to choose heavier ions such as nitrogen, in consideration of their demonstrated efficacy in mixing the gold deposit. The treatment time is thus reduced. In this case, the necessary doses are low and there is little risk of modifying the electrical, mechanical or aesthetic properties of the deposits.
In addition, it is noted that by reducing the thickness of the gold deposits, the average radius of the pores is increased. For the treatment, it is possible to envisage gradually changing from the use of nitrogen ions to helium ions insofar as the angles of incidence are increased.

To increase the efficacy of the treatment while reducing the cost thereof, the method of the invention recommends, according to an embodiment, the use of cyclotron resonance sources (ECR). These sources have the special properties of being compact and producing multicharged ions, therefore more energetic for the same extraction voltage. Moreover, these sources are robust and consume little electricity. In consideration of their size, these sources can be arranged in series or in parallel in order to multiply the treatment capacity of the machines. Their intensities, on the order of 10 mA, enable strips several mm wide at speeds on the order of several meters per minute. These treatment speeds are industrially acceptable.

The method of the invention proposes, by way of example, treating the porosities of gold deposits. It can be used with other metals that have similar porosity problems.

The energy of the ion beam is preferably greater than or equal to 10 keV. Such an energy is selected because it enables cascades of atoms to be created after an ion impact.

As an example, the following treatment conditions are proposed:
for a gold deposit with a thickness of 0.1 μM, a nitrogen beam perpendicular to the deposit and with an energy on the order of 60 keV or higher enables both effective mixing and passage through the deposit;
for a gold deposit with a thickness of 0.4 μm, a helium beam perpendicular to the deposit and with an energy on the order of 100 keV or higher enables both effective mixing and passage through the deposit.

As an example, table 1 provides examples of choices of parameters for the porosity treatment in a gold layer, based on the ion used (helium or nitrogen), the thickness, e, of the gold deposit, and the radius, R, of the pores to be treated. In the table, “αₘ” corresponds to the minimum angle of incidence, “L” corresponds to the course of the ion passing through the deposit, “Eₘᵢₙ” corresponds to the minimum energy to be provided in order to pass through the deposit, the ratio “A” corresponds to the movement of the atoms per Angstrom and per incident ion, the value “D” corresponds to the dose required in order to move each atom of the thickness of the deposit (expressed as 10¹⁶ ions per cm²) one time and the value “ep” corresponds to the thickness sprayed (in Angstrom). The data mentioned correspond to treatments with an ECR source in which the extraction voltage is 45 kV. Helium ions He+ of 45 keV and He2+ of 90 keV or nitrogen ions primarily in the form N+ of 45 keV, N2+ of 90 keV, N3+ of 135 keV are thus obtained.

TABLE 1

| ion | e(μm) | R(μm) | αₘ(°) | L(μm) | Eₘᵢₙ(KeV) | A | D | ep(Å) |
|---|---|---|---|---|---|---|---|---|
| He | 0.1 | 0.1 | 45 | 0.14 | 20 | 0.03 | 2 | 10 |
| | | 0.5 | 78 | 0.50 | 100 | 0.03 | 2 | 10 |
| | | 0.8 | 82 | 0.80 | 200 | 0.03 | 2 | 10 |
| | 0.2 | 0.1 | 26 | 0.22 | 40 | 0.03 | 4 | 20 |
| | | 0.5 | 68 | 0.53 | 110 | 0.03 | 4 | 20 |
| | | 0.8 | 75 | 0.82 | 210 | 0.03 | 4 | 20 |
| | 0.4 | 0.1 | 14 | 0.41 | 75 | 0.03 | 8 | 40 |
| | | 0.5 | 51 | 0.64 | 150 | 0.03 | 8 | 40 |
| | | 0.8 | 63 | 0.89 | 300 | 0.03 | 8 | 40 |
| N | 0.1 | 0.1 | 45 | 0.14 | 60 | 0.3 | 0.2 | 10 |
| | | 0.5 | 78 | 0.50 | 350 | 0.3 | 0.2 | 10 |
| | | 0.8 | 82 | 0.80 | 600 | 0.3 | 0.2 | 10 |
| | 0.2 | 0.1 | 26 | 0.22 | 150 | 0.3 | 0.4 | 20 |
| | | 0.5 | 68 | 0.53 | 300 | 0.3 | 0.4 | 20 |
| | | 0.8 | 75 | 0.82 | 600 | 0.3 | 0.4 | 20 |
| | 0.4 | 0.1 | 14 | 0.41 | 300 | 0.3 | 0.8 | 40 |
| | | 0.5 | 51 | 0.54 | 400 | 0.3 | 0.8 | 40 |
| | | 0.8 | 63 | 0.89 | 700 | 0.3 | 0.8 | 40 |

In addition, the inventors were able to observe that it may be advantageous to limit the quantity of implanted ions to around 5% of the atomic concentration, in particular in the case of helium.

### BRIEF DESCRIPTION OF THE DRAWINGS

Other special features and advantages of this invention will appear in the following description of non-limiting examples of embodiments in reference to the appended drawings in which:

FIG. 1 is a diagrammatic cross-section view of a metal deposit on a substrate,

FIG. 2 is a diagrammatic cross-section view of the implementation of the method according to the invention,

FIG. 3 is a view of potentiometric curves of samples treated according to the invention and a comparative sample,

FIG. 4 is a view of a device for implementing this invention.

### DETAILED DESCRIPTION OF THE EMBODIMENTS

For the sake of clarity, the various elements shown in these figures are not necessarily shown to scale.

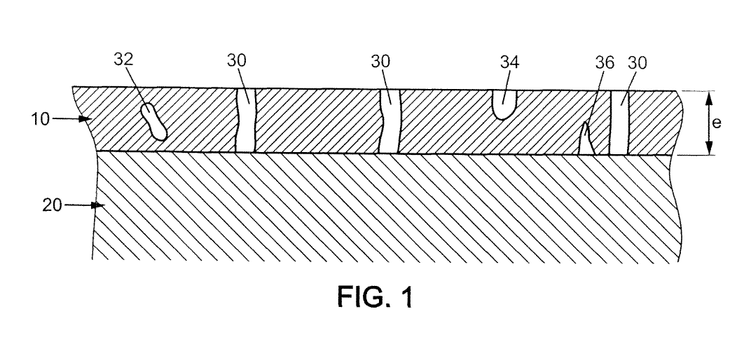

FIG. 1 shows a porous metal deposit 10, with a thickness e, deposited on a substrate 20.

A plurality of types of porosity may exist in a porous metal deposit 10. In the case of electrolytic deposits, it is observed that the porosities develop essentially in a direction perpendicular to the surface of the substrate on which the deposit is produced. As an example, the porosities 30 are substantially cylindrical and lead both to the substrate and the external surface of the metal deposit. Porosities 32, 36 are closed porosities, formed respectively within the metal deposit or at the interface with the substrate.

Porosities 34 are porosities leading to the external surface of the metal deposit, but not leading to the substrate.

Porosities 30 are capable of allowing corrosive agents to pass and causing corrosion of the substrate.

The method according to the invention is intended to fill these porosities 30, but it is also capable of enabling rearrangements of material capable of filling the porosities 32, 34 and 36.

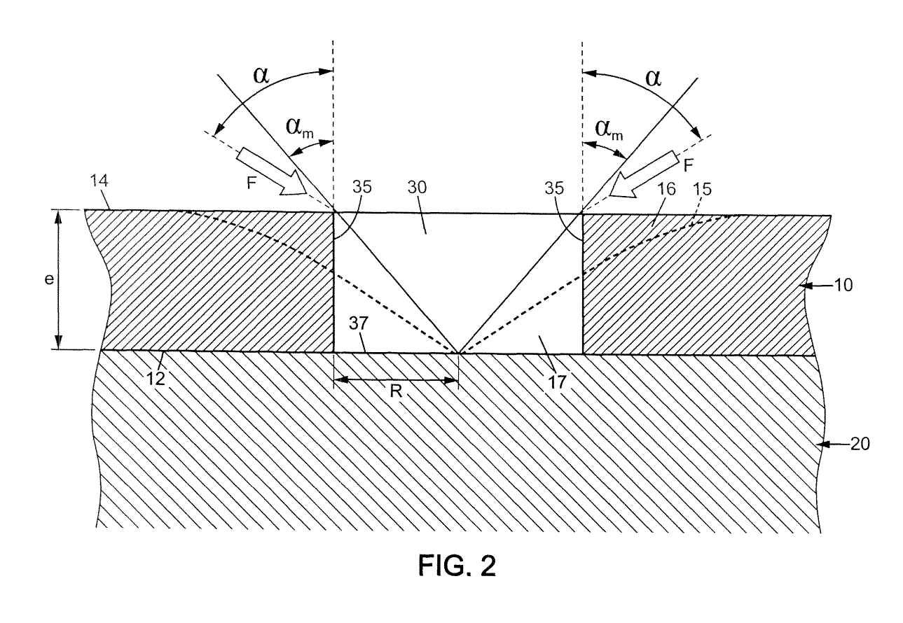

FIG. 2 shows the treatment of a pore with an ion beam F.

The metal deposit 10 is formed on a substrate 20 and its thickness e is determined between the lower face 12 of said deposit in contact with the substrate and the opposite external face 14. A pore 30 is shown, with a cylindrical shape and limited by its well 35 and its base 37 corresponding to an area of the substrate 20 on which the metal deposit 10 is deposited.

To at least partially fill this pore 30, an ion beam F is directed at the surface 14 of the deposit. The beam is oriented according to an angle α, determined with respect to the normal to the surface 14, where α is greater than an angle αₘ of minimal incidence, of which the tangent is the ratio of the radius R of the pore to the thickness e of the metal deposit.

When the ions of the beam F bombard the surface 14, in particular according to the selected incidence, the atoms located at the edge of the pore are mixed and capable of filling the pore. The profile 15 of the pore filled by the atoms that have been mixed on the edges of the pore during implantation is shown with a dotted line. The atoms initially present in area 16, located between the profile 15 and the wall 35 are moved and fill area 17 located between the profile 15 and the initial base 37 of the pore. In the example shown, the metal deposit is subjected to two beams oriented according to an angle α, in the same plane perpendicular to the surface 14. It is noted that this configuration advantageously enables the pore 30 to be filled.

It is noted that when the angle of incidence is greater than the minimum angle of incidence, the base of the pore is filled more effectively than when the angle of incidence equal to the minimum angle of incidence, but the energy of the ions has to be sufficient to pass through the apparent thickness which by the same token increases.

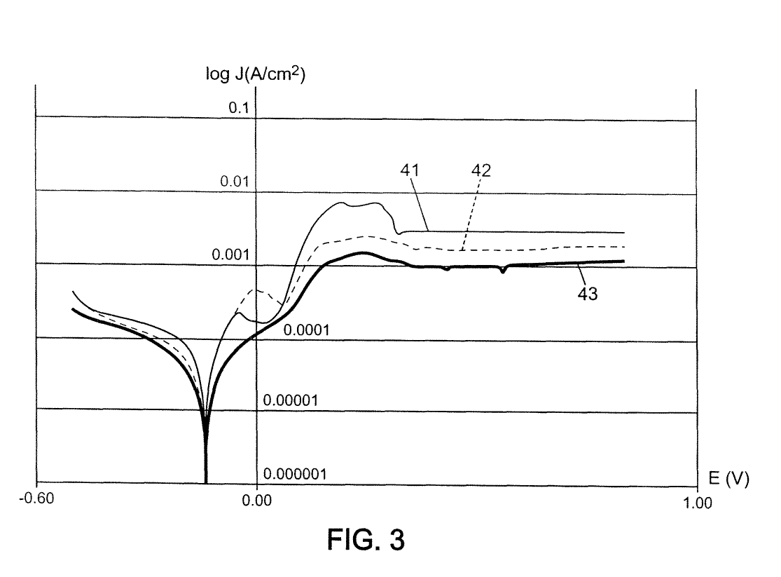

FIG. 3 shows potentiometric curves obtained for:
a deposit of free gold forming a comparative sample, curve 41;
a deposit of gold treated according to the invention by a perpendicular nitrogen beam, curve 42;
a deposit of gold treated according to the invention by a helium beam, curve 43, at an angle of 45° and in four perpendicular directions.

The gold deposits were produced electrolytically on a nickel substrate. The deposited gold has a thickness of 0.8 μm and corresponds to pure gold.

The solution used is H₂SO₄ at 0.5 M. A decrease in the corrosion current by a factor of 2 for nitrogen and a factor of 3 to 4 for helium was observed. In both cases, this decrease in the corrosion current results in a decrease in porosity due to the treatment. The nitrogen dose implanted is four times greater than that of helium. However, a greater efficacy of the treatment is observed with helium. This is explained by the optimization of the ballistic mixing obtained in four perpendicular directions, and at a same angle of incidence of 45°.

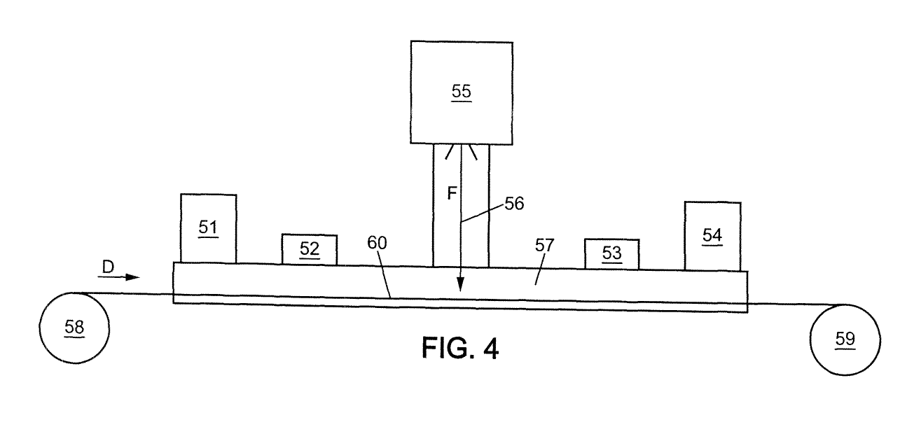

FIG. 4 shows a moving strip treatment machine. The strip 60 consists of a substrate and a porous metal deposit to be treated.

For a moving strip treatment machine, a differential vacuum column 56 should be placed between the ECR source 55. Indeed, a vacuum of 10⁻⁶ mbar is recommended for the production of plasma in the source and a vacuum of 10⁻⁴ mbar is sufficient for treating the strip in the chamber 57. The differential vacuum column 56 is intended to allow the beam F to pass while preventing gas from rising in the plasma chamber. The differential vacuum column 56 is equipped with a turbomolecular pumping system enabling the rising gas to be trapped. Two airlocks, one at the inlet, the other at the outlet, are equipped with a primary pumping system 51 and 54 and a turbomolecular pumping system 52 and 53 enabling the strip to pass 60 and a vacuum to be created in the treatment chamber 57. The speed of movement of the strip on the unwinder/winder 58, 59 is calculated so as to obtain the dose required to treat the metal deposit, in particular gold supported by the strip. To avoid the risk of heating, which may cause the strip to break, the speed of movement may be increased and the number of forward and reverse passes can be proportionally multiplied.

The invention is not limited to the embodiments exemplified and must be interpreted as being non-limiting and encompassing any equivalent embodiment. It should be noted that if examples of electrolytic depositions were presented, the method according to the invention could be applied to any type of metal deposit, for example obtained by gas, such as for example CVD or PVD or any other technique suitable for producing a metal deposit on a substrate. It should also be noted that if examples of gold deposits were presented, the method according to the invention is also capable of reducing, or even filling, the porosity of deposits of other metals, for example silver, nickel, platinum, zinc, tin or alloys.

1. Method for ion treatment of the porosity of a porous metal deposit deposited on a substrate including a step in which the surface of said metal deposit is subjected to an ion beam (F).

2. Treatment method according to claim 1, wherein the ion beam is emitted by a cyclotron resonance source (ECR).

3. Treatment method according to claim 1, wherein the angle of incidence (α) of the ion beam is between a minimum angle of incidence (αₘ) and substantially 80°, in which the angle of incidence (α) of the beam is measured with respect to the normal to the surface of the porous metal deposit to be treated and in which the minimum angle of incidence (αₘ) is determined according to the radius (R) of the pores and the thickness (e) of the metal deposit to be treated according to the formula:
αₘ=arc tg(R/e)

4. Treatment method according to claim 1, wherein the angle of incidence (α) of the ion beam is substantially coincident with the normal to the surface of the metal deposit to be treated.

5. Treatment method according to claim 1, wherein the beam is oriented in two opposite

6. Treatment method according to claim 1, wherein the beam is oriented with respect to the surface of the porous metal deposit according to a plurality of angles of incidence and/or a plurality of planes substantially perpendicular to the surface of the metal deposit to be treated.

7. Treatment method according to claim 6, wherein the beam is oriented successively according to the same angle of incidence α, and according to four directions which are deduced by a 90° rotation with respect to the axis perpendicular to the surface, namely with respect to the normal to the surface of the metal deposit to be treated.

8. Treatment method according to claim 1, wherein the total dose of implanted ions is calculated so as to enable the movement of each metal atom in the implantation depth at least once.

9. Treatment method according to claim 1, wherein the ion beam is formed by ionized atoms in which the atoms are chosen from the list consisting of helium (He), nitrogen (N), neon (Ne), argon (Ar), krypton (Kr) and xenon (Xe).

10. Treatment method according to claim 1, wherein the ion beam extraction voltage is greater than or equal to 10 kV.

11. Treatment method according to claim 1, wherein the porous metal deposit is an electrolytic deposit.

12. Treatment method according to claim 1, wherein the porous metal deposit is a gold deposit.
